(19) United States
(12) Patent Application Publication
(10) Pub. No.: US 2025/0151470 A1
(43) Pub. Date: May 8, 2025

(54) LIGHT-EMITTING DIODE AND LIGHT-EMITTING DEVICE

(71) Applicant: Quanzhou sanan semiconductor technology Co., Ltd., Fujian (CN)

(72) Inventors: Weiming YU, Fujian (CN); HsiuLi HUANG, Fujian (CN); Chuncheng ZHAO, Fujian (CN); Yanling YU, Fujian (CN); Chungying CHANG, Fujian (CN); Chiming TSAI, Fujian (CN); Shaohua HUANG, Fujian (CN)

(73) Assignee: Quanzhou sanan semiconductor technology Co., Ltd., Fujian (CN)

(21) Appl. No.: 18/935,629

(22) Filed: Nov. 3, 2024

(30) Foreign Application Priority Data
Nov. 8, 2023 (CN) 202311482265.5

(51) Int. Cl. H01L 33/20; H01L 33/62

(52) U.S. Cl. CPC H10H 20/819; H10H 20/857

(57) ABSTRACT

A light-emitting diode and a light-emitting device are provided. The light-emitting diode includes a semiconductor stack layer and a first electrode. The semiconductor stack layer has a light output surface and a back surface opposite to each other. On the back surface, the semiconductor stack layer has a first mesa exposing a first semiconductor layer thereof and a second mesa adjacent to the first mesa. The first electrode formed on the back surface of the semiconductor stack layer at least surrounds a portion of the second mesa, and the first electrode surrounding a portion of the second mesa extends toward the light output surface. The first electrode has a first chamfer portion, and the second mesa has a second chamfer portion. The first electrode and the second mesa have a minimum distance L, and a radius of curvature of the second chamfer portion is greater than or equal to \sqrt{2}L.

### CROSS-REFERENCE TO RELATED APPLICATION

This application claims the priority benefit of China application serial no. 202311482265.5, filed on Nov. 8, 2023. The entirety of the above-mentioned patent application is hereby incorporated by reference herein and made a part of this specification.

### BACKGROUND

### Technical Field

The disclosure relates to the technical field of semiconductor manufacturing, and in particular, relates to a light-emitting diode and a light-emitting device.

### Description of Related Art

In recent years, with the advancement of technology and the iteration of products, the market demand for the luminous brightness (Lumen Output Per Watt, LOP) of light-emitting diodes (LEDs) has increased. However, in the pursuit of brighter designs, product reliability may be sacrificed to a certain extent. For instance, the brightness can be increased by increasing the area of the light-emitting region. However, as the area of the light-emitting region increases, the spacing between the light-emitting region and other functional structures will become smaller if the size of the LED chip remains unchanged. Especially at the tip position of the corner of the light-emitting region, the uniformity of electric field distribution of the chiplet is poor. The concentration of electrons and electron holes in the tip region increases, the tip effect is enhanced, and the anti-electro-static (electro-static discharge, ESD) ability of the uniformity is weakened. During the production, transportation, and customer use of LEDs, ESD breakdown and chiplet leakage may thus occur easily. For electronic equipment and elements, electro-static discharge may come from interference from multiple complex factors such as the human body, equipment, or environment. These electro-static discharge events may have a direct negative impact on the performance and service life of the equipment or elements. Equipment or elements with good ESD resistance can better resist electro-static discharge events, and their stability during normal use is also improved.

Therefore, in the process of LED design and manufacturing, it is necessary to provide an improved technical solution for the abovementioned deficiencies in the related art to ensure the reliability of the LEDs during use.

### SUMMARY

In view of the abovementioned defects and shortcomings of light-emitting diode in the related art, the disclosure aims to provide a light-emitting diode and a light-emitting device, and by optimizing a design structure of a chamfer portion of a light-emitting region, the ability of the light-emitting diode to withstand forward ESD is improved, and product reliability is further enhanced.

In the first aspect, the disclosure provides a light-emitting diode at least including a semiconductor stack layer and a first electrode.

The semiconductor stack layer has a light output surface and a back surface opposite to each other, and includes a first semiconductor layer, an active layer, and a second semiconductor layer stacked in sequence in a direction from the light output surface to the back surface. On one side of the back surface, the semiconductor stack layer has a first mesa exposing the first semiconductor layer and a second mesa adjacent to the first mesa.

The first electrode is formed on the back surface of the semiconductor stack layer and at least surrounds a portion of the second mesa, and the first electrode surrounding a portion of the second mesa extends toward the light output surface.

In a top view direction of the semiconductor stack layer, the first electrode has a first chamfer portion, the second mesa has a second chamfer portion, and the first chamfer portion and the second chamfer portion are arranged correspondingly.

The first electrode and the second mesa have a minimum distance L, and a radius of curvature of the second chamfer portion is greater than or equal to \sqrt{2}L.

In the second aspect, the disclosure further provides a light-emitting diode at least including a semiconductor stack layer and a first electrode.

The semiconductor stack layer has a light output surface and a back surface opposite to each other, and includes a first semiconductor layer, an active layer, and a second semiconductor layer stacked in sequence in a direction from the light output surface to the back surface. On one side of the back surface, the semiconductor stack layer has a first mesa exposing the first semiconductor layer and a second mesa adjacent to the first mesa.

The first electrode is formed on the back surface of the semiconductor stack layer and at least surrounds a portion of the second mesa, and the first electrode surrounding a portion of the second mesa extends toward the light output surface.

In a top view direction of the semiconductor stack layer, the first electrode has a first chamfer portion, the second mesa has a second chamfer portion, and the first chamfer portion and the second chamfer portion are arranged correspondingly.

A ratio of a radius of curvature of the second chamfer portion to a radius of curvature of the first chamfer portion is greater than or equal to 1.

In the third aspect, the disclosure further provides a light-emitting device including a circuit substrate and a light-emitting element fixed to the circuit substrate, and the light-emitting element includes the light-emitting diode in the above technical solution.

Compared to the related art, beneficial effects produced by the technical solution of the disclosure include the following.

In the technical solution provided by the disclosure, by designing a chamfer at the corner of the light-emitting region of the chiplet, the corner structure with folded corners or right angles is optimized into a corner structure with an arc-shaped chamfer. Moreover, by further defining the radius of curvature of the chamfer portion of the light-emitting region, the relative distance between the electrode structure at the corner of the region and the corresponding tip structure of the light-emitting mesa in the top view direction is defined, so that the mesas in the light-emitting region all have arc transition edges, and no sharp-angle structures are produced. Through this design, the carriers are distributed more uniformly in the chiplet instead of being concentrated at the corner tip of the light-emitting region. Further, by increasing the relative distance between the electrode structure and the chamfer position of the light-emitting mesa, electro-static breakdown is also be avoided. In the technical solution of the disclosure, the leakage problem caused by excessive tip effect is effectively avoided, the ability of light-emitting diodes to withstand forward ESD is improved, and thus the product reliability is enhanced.

In addition, in the technical solution of the disclosure, by defining the ratio of the radius of curvature of the chamfer of the electrode structure in the light-emitting region to the radius of curvature of the chamfer of the light-emitting mesa, the relative distance between the electrode structure and the corresponding tip structure of the light-emitting mesa is defined. Further, the ratio of the radius of curvature of the chamfer portion of the light-emitting region to the radius of curvature of the chamfer portion of the outer electrode structure in the top view direction is further defined to be greater than or equal to 1. In this way, the distance between the light-emitting region and the electrode structure at the corresponding rounded corners is always greater than the minimum distance when the two are in a parallel position relationship. The problem of leakage caused by charge accumulation caused by the tip effect is decreased, the ability of the light-emitting diode to withstand forward ESD is improved, and the product reliability is further enhanced.

In addition, the light-emitting device provided by the disclosure uses the light-emitting diode with good reliability provided in the above technical solution, so the light-emitting device also has good light output effect and improved service life.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic view of a top view structure of a light-emitting diode in the related art.

FIG. 2 is a schematic view of a cross-sectional structure of the light-emitting diode in the related art.

FIG. 3 is a schematic view of a top view structure of a light-emitting diode according to Example 1 of the disclosure.

FIG. 4 is a partially-enlarged schematic view of an embodiment of the light-emitting diode in FIG. 3.

FIG. 5 is a partially-enlarged schematic view of an embodiment of the light-emitting diode in FIG. 3.

FIG. 6 is a partially-enlarged schematic view of a light-emitting diode provided in a Comparative Example of Example 1.

FIG. 7 is a schematic view of a top view structure of a light-emitting diode according to Example 2 of the disclosure.

FIG. 8 is a partially-enlarged schematic view of an embodiment of the light-emitting diode in FIG. 7.

FIG. 9 is a partially-enlarged schematic view of an embodiment of the light-emitting diode in FIG. 7.

FIG. 10 is a schematic view of a structure of a light-emitting device according to the disclosure.

### DESCRIPTION OF THE EMBODIMENTS

In a vertically-structured light-emitting diode (LED), epitaxial materials such as gallium nitride are transferred from a growth substrate to a substrate material such as silicon that has good electrical and thermal conductivity properties through chip preparation processes such as thermal compression bonding and laser lift-off. In this way, the electrodes of the components are distributed vertically up and down, and the current is injected in the vertical direction. A series of problems such as heat dissipation, uneven current distribution, and poor reliability caused by electrode plane distribution and lateral current injection in lateral and flip-chip structured light-emitting diode devices are solved.

As is known, the tip effect refers to the phenomenon that the electric field is concentrated at the tip or sharp corner of a structure. In the PN structure of a light-emitting diode, when current is injected, the electric field accumulates at the edge and tip of the PN junction, which causes the concentration of electrons and electron holes in the tip region to increase, forming a stronger electric field. The enhanced tip effect can improve the luminous efficiency and brightness of light-emitting diodes. However, if the tip effect is excessively obvious, the uneven distribution of the electric field inside the chiplet may lead to excessive current concentration and local hot spots. As a result, the performance and service life of light-emitting diodes are damaged, and the performance of the chiplet is affected.

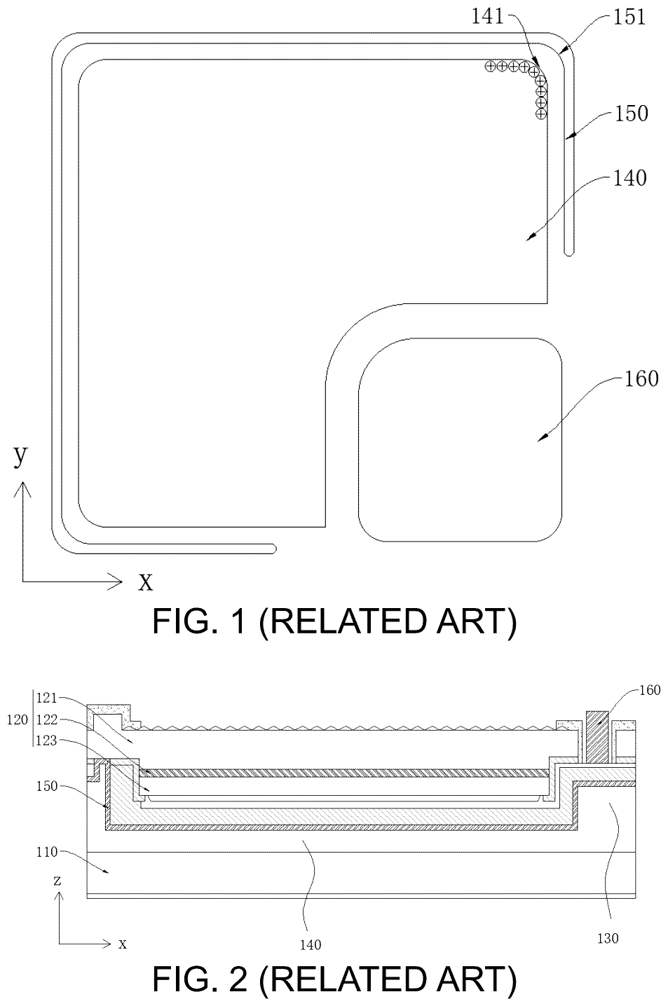

With reference to FIG. 1 and FIG. 2, a light-emitting diode having a vertical structure in the related art is shown. FIG. 1 to FIG. 2 provide a chip design of a chamfer portion of a light-emitting region of a light-emitting diode in the related art. While such a design obtains a larger light-emitting area, it also brings certain disadvantages. A first electrode (N electrode) surrounds the light-emitting region, causing current to easily gather at a tip position at a corner between the light-emitting region and the first electrode (N electrode). This causes the tip effect of a chiplet to be excessively enhanced and the electro-static discharge (ESD) resistance of the chiplet to be weakened. For vertically-structured light-emitting diodes, ESD breakdown is prone to occur during production, transportation, and user use, resulting in current intensity reverse (IR) leakage of the chiplet. IR is an important parameter when testing a light-emitting diode, and generally, when IR≥10 μA, this light-emitting diode is determined as a defective product. Therefore, the above problems may considerably affect the photoelectric characteristics of light-emitting diodes.

In view of the above defects, the implementation of the disclosure is illustrated below by specific embodiments. A person having ordinary skill in the art can easily understand other advantages and effects of the disclosure from the content disclosed in this specification. The disclosure can also be implemented or applied through other different specific implementation ways. The details in this specification can also be modified or changed based on different viewpoints and applications without departing from the spirit of the disclosure.

For the ease of description, the coordinate system is defined as follows, with reference to FIG. 1 and FIG. 2: the directions of the two adjacent edges of light-emitting mesas are the x-axis and the y-axis, and the direction perpendicular to the xy plane is the z-axis, which is also the formation direction of a semiconductor stack layer.

### Example 1

With reference to FIG. 2 to FIG. 5, in this embodiment, a light-emitting diode is provided, and the light-emitting diode at least includes a semiconductor stack layer 120 and a first electrode 150 formed on a back surface of the semiconductor stack layer 120.

Specifically, the semiconductor stack layer 120 has a light output surface and the back surface opposite to each other, and includes a first semiconductor layer 121, an active layer 122, and a second semiconductor layer 123 stacked in sequence in a direction from the light output surface to the back surface. On one side of the back surface of the semiconductor stack layer 120, the semiconductor stack layer 120 has a first mesa 130 exposing the first semiconductor layer 121 and a second mesa 140 adjacent to the first mesa 130. It can be understood that the first semiconductor layer 121 may be an N-type semiconductor layer and provides electrons to the active layer 122 under the action of a power source. The active layer 122 may be a quantum well (QW) structure or a multiple quantum well (MQW) structure. A composition and a thickness of a well layer in the active layer 122 determine a wavelength of the generated light. By changing the depth of the quantum wells, the number of pairs of quantum wells and quantum barriers, the thickness and/or other features in the active layer, the luminous efficiency may be improved. The second semiconductor layer 123 may be a P-type semiconductor layer and provides electron holes to the active layer 122 under the action of the power supply. Accordingly, a light output direction of the light output surface is away from a stack forming direction of the second mesa 140.

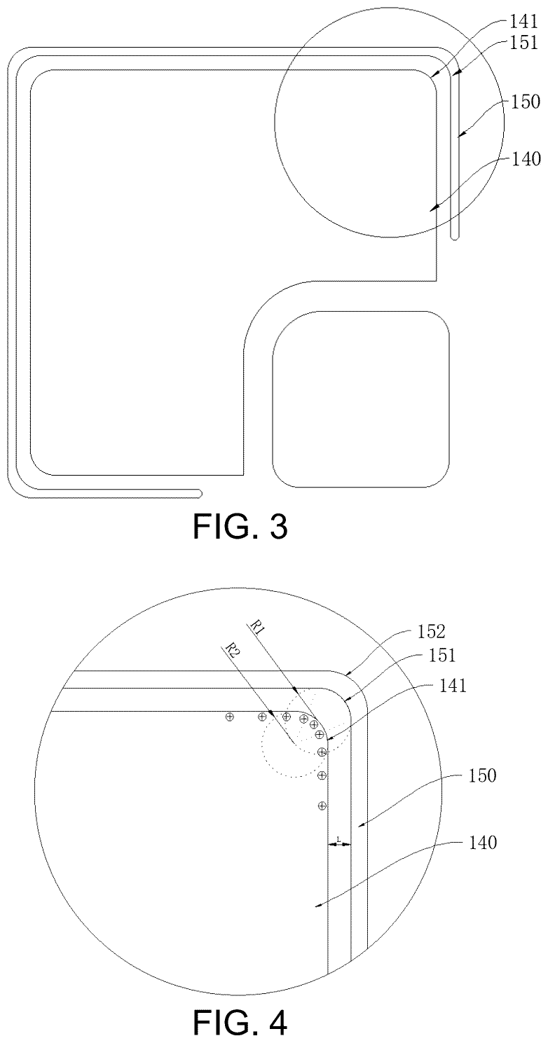

The first electrode 150 is formed on the back surface of the semiconductor stack layer 120, and the first electrode 150 surrounds at least a portion of the second mesa 140 in the xy plane. With reference to FIG. 1 or FIG. 3, approximately three quarters of an edge of the second mesa 140 is surrounded by the first electrode 150, and the first electrode 150 surrounding an edge region of the second mesa 140 extends toward the light output surface. That is, the first electrode 150 extends in a direction away from the second mesa 140 to form a good ohmic contact with the first semiconductor layer 121.

Herein, in a top view direction of the semiconductor stack layer 120, the first electrode 150 has a first chamfer portion 151, the second mesa 140 has a second chamfer portion 141, and the first chamfer portion 151 and the second chamfer portion 141 are arranged correspondingly. That is, the first electrode 150 surrounding the second chamfer portion 141 of each second mesa 140 has the first chamfer portion 151. With reference to FIG. 3 or FIG. 4, the first electrode 150 and the second mesa 140 have a minimum distance L, and a radius of curvature of the second chamfer portion 141 is greater than or equal to \sqrt{2}L. It can be understood that the minimum distance L is the spacing when the second mesa 140 and a side of the first electrode 150 are in a parallel position relationship. In the above technical solution, a relative distance between the first electrode 150 and a tip structure corresponding to the second mesa 140 is defined by defining the radius of curvature of the second chamfer portion 141. A radius of curvature R2 of the second chamfer portion 141 is defined to be greater than or equal to \sqrt{2}L to optimize the rounded corner design of the second mesa 140, that is, R2≥\sqrt{2}L. As the minimum distance L changes, the radius of curvature R2 is always set according to a numerical constraint ratio with reference to the minimum distance L. For a small-sized chip or when the distance between the first electrode 150 and the second mesa 140 is decreased according to chip design requirements, the radius of curvature R2 is also decreased to lower light output area loss caused by the excessively-large rounded corner and to improve the light-emitting intensity. When a designed gap between the first electrode 150 and the second mesa 140 is relatively large, in order to ensure that there is a sufficient gap between the first chamfer portion 151 and the second chamfer portion 141, the radius of curvature R2 is also increased. The parameter constraint conditions of the technical solution may be applied to light-emitting diodes of various designs and specifications. The second mesa does not have a sharp corner structure, and the carrier distribution is uniform, rather than being concentrated at the corner between the first electrode and the second mesa. The leakage problem caused by excessive tip effect is effectively avoided, the ability of light-emitting diodes to withstand forward ESD is improved, and thus the product reliability is enhanced.

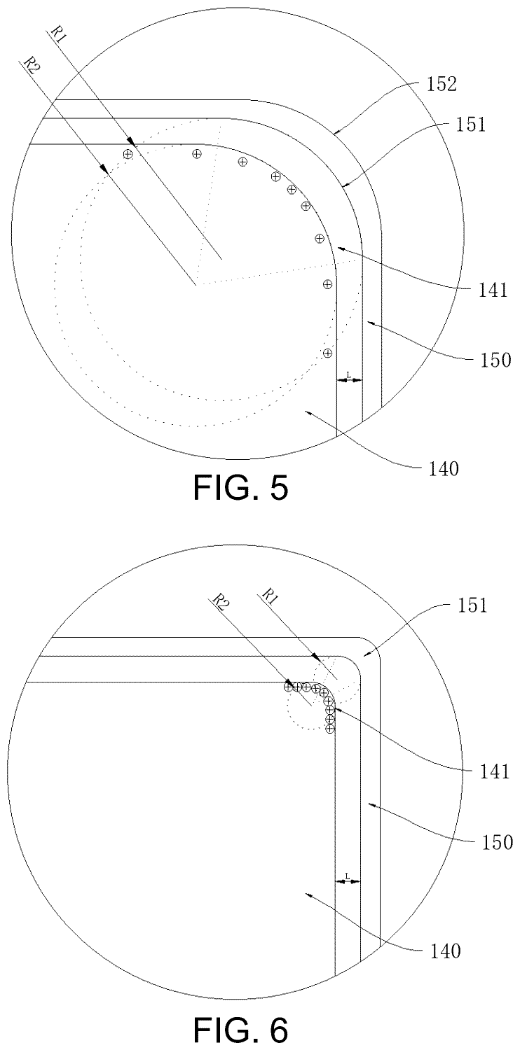

With reference to FIG. 3 to FIG. 5, FIG. 3 provides a schematic view of a top view structure of a light-emitting diode having the first chamfer portion 151 and the second chamfer portion 141 with equal curvature variations. FIG. 4 to FIG. 5 provide schematic views of top view structures of a light-emitting diode with the first chamfer portion 151 and the second chamfer portion 141 having the same radius of curvature under different radius of curvature conditions.

In an embodiment, a radius of curvature R1 of the first chamfer portion 15 is greater than or equal to \sqrt{2}L, that is, R1≥\sqrt{2}L. By defining the radius of curvature of the first chamfer portion 151 of the first electrode 150 and the radius of curvature of the second chamfer portion 141 of the second mesa 140 to be greater than or equal to \sqrt{2}L, the first electrode 150 does not have sharp corners, and the spacing between the two may be relatively moderately changed. This is conducive to uniform distribution of carriers, and excessive concentration of carriers may not occur at the first chamfer portion 151 and the second chamfer portion 141.

In an embodiment, with reference to FIG. 3 to FIG. 5, the minimum distance L between the first electrode 150 and the second mesa 140 is in a range of 2 μm to 10 μm. If the electrode is in direct contact with or is excessively close to a light output mesa, ESD breakdown or short circuit may occur, a LED device may thus be damaged, and the photoelectric performance is thereby lowered. An appropriate spacing between the electrode and the light output mesa may reduce the concentration of the electric field, which helps to improve the light output efficiency and brightness of the LED. The improved spacing may also be used to design heat dissipation and packaging structures to ensure that the LED device may effectively dissipate heat when working for a long time, and the service life of the LED is thus extended. However, if the spacing is excessively large, the effective light-emitting area may be lost, resulting in a decrease in brightness. Therefore, the minimum distance L between the first electrode 150 and the second mesa 140 is defined to a range of 2 μm to 10 μm to balance the performance of the above light emitting-diode. As an example, the minimum distance L may be 2 μm, 4 μm, 5.5 μm, 8 μm, or 10 μm. In this embodiment, the minimum distance L is 5.5 μm.

As an example, with reference to FIG. 4, the radius of curvature RI and the radius of curvature R2 may be 7.78 μm, which is equal to \sqrt{2}L. Alternatively, with reference to FIG. 5, the radius of curvature R1 and the radius of curvature R2 may both be greater than \sqrt{2}L, for example, both are 10 μm, 20 μm, or 30 μm. As shown in FIG. 4 and FIG. 5, when R1=R2=7.78 μm=\sqrt{2}L, the charge distribution at the edge of the light output mesa is relatively dispersed, and the electric field distribution of the light-emitting diode may basically avoid ESD breakdown and leakage caused by the tip effect. As the radius of curvature R1 and the radius of curvature R2 increase, the charge distribution at the edge of the light output mesa becomes more dispersed, the electric field distribution becomes more uniform, and the carrier distribution becomes more dispersed. According to the test results, the forward ESD capability of the optimized light-emitting diode is improved, especially for the large rounded corner design provided in FIG. 5, its forward ESD capability can reach 4000V, so that the photoelectric performance and service life of the light-emitting device is significantly improved.

For comparison, FIG. 6 provides a schematic view of a rounded corner structure of a light-emitting region when the minimum distance L=5.5 μm and R1=R2<\sqrt{2}L. The Comparative Example of the light-emitting diode with the rounded corner structure has a worse forward ESD capability test performance than the light-emitting diode of the related art. Therefore, the electric field uniformity of the light-emitting diode under the rounded corner parameter setting is still low, and carrier aggregation is prone to occur at the tip of the structure, thereby bringing the risk of leakage.

In an embodiment, the second mesa 140 has a shortest side, and the radius of the first chamfer portion 151 and the radius of the second chamfer portion 141 are both less than half of a length of the shortest side. When the second mesa 140 is a square, the radii of curvature of three adjacent second chamfer portions 141 are all equal to half the side length of the second mesa 140. The second mesa 140 defined by the rounded corner parameter may be close to a circle, sacrificing an appropriate light-emitting area to avoid leakage problems caused by the tip effect to the greatest extent.

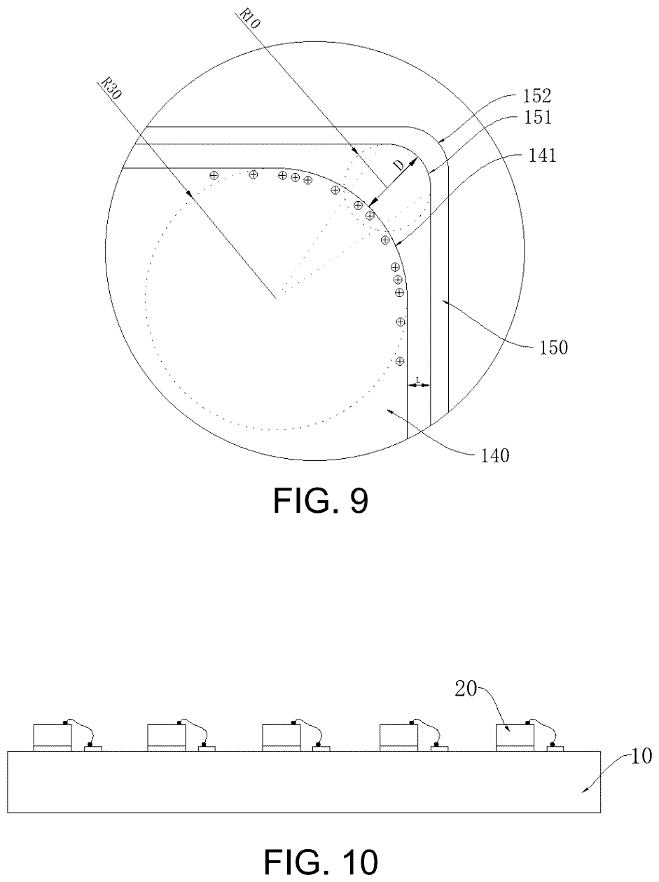

In an embodiment, the radius of curvature of the second chamfer portion 141 is the same as or different from the radius of curvature of the first chamfer portion 151. Under the premise that a minimum radius of curvature of a rounded corner of the first electrode 150 is greater than or equal to \sqrt{2}L, the second mesa 140, its corresponding second chamfer portion 141, and the first chamfer portion 151 can maintain the same curvature radius change, so that a relatively moderate spacing change is obtained. This is more conducive to the uniform distribution of the electric field, and the accumulation of carriers at the rounded corner is also avoided. The radius of curvature of the second chamfer portion 141 may also be adjusted individually according to the manufacturing process of the first electrode 150 or other actual requirements, and the overall optimal light output brightness and photoelectric performance may thus be obtained. Specifically, FIG. 4, FIG. 5, and FIG. 8 provide schematic views of light-emitting diode structures in which the second chamfer portion 141 and the first chamfer portion 151 have the same curvature radius variation. FIG. 9 provides a schematic view of a light emitting diode structure in which the second chamfer portion 141 and the first chamfer portion 151 have different curvature radius variations, and this technical solution is to be described in detail in Example 2.

In the above embodiment, the radius of curvature of the second chamfer portion 141 is 10 μm to 60 μm. Further, the radius of curvature of the second chamfer portion 141 is in the range of 15 μm to 45 μm, so as to reduce the charge accumulation at the corner of the second mesa 140 as much as possible. In this way, a relatively large light output area is retained, brightness loss is reduced, and a performance balance is achieved. As an example, the radius of curvature of the second chamfer portion 141 may be 10 μm, 15 μm, 20 μm, 30 μm, 45 μm, 50 μm, or 60 μm.

In the above embodiment, the radius of curvature of the first chamfer portion 151 is 5 μm to 60 μm. Further, the first chamfer portion 151 has a radius of curvature of 5 μm to 40 μm to match the round-corner structure of the second chamfer portion 141. As an example, the first chamfer portion 151 may have a radius of curvature of 5 μm, 10 μm, 20 μm, 30 μm, 40 μm, 50 μm, or 60 μm.

In an embodiment, the ratio of the radius of curvature of the second chamfer portion 141 to the radius of curvature of the first chamfer portion 151 is greater than 1, that is, R2:R1>1. The radius of curvature of the second chamfer portion 141 is different from the radius of curvature of the first chamfer portion 151, and the rounded corner of the second mesa 140 is greater than the rounded corner of the first electrode 150. Therefore, the distance between the second mesa 140 located at the chamfer and the first electrode 150 is greater than the minimum distance L when the two are in a parallel position relationship. Under the premise of controlling the minimum radius of curvature of the second chamfer portion 141, making the second mesa 140 further away from the first electrode 150 at the chamfer may further prevent the chiplet leakage phenomenon caused by ESD breakdown. This technical solution is particularly suitable for a small-sized chiplet or a chiplet with a small distance L between the light-emitting region and the electrode structure. For a small-sized chiplet, it light-emitting brightness mainly depends on the area of the light-emitting region. If the radius of curvature of the chamfer is designed to be excessively large, it may lead to a loss of light-emitting area. The reduction in tip effect caused by increasing the chamfer curvature radius is not sufficient to compensate for the decrease in brightness caused by the loss of the light-emitting area. Therefore, the above problem may be effectively improved by limiting R2:R1>1. Further, the ratio of the radius of curvature of the second chamfer portion 141 to the radius of curvature of the first chamfer portion 151 is between 1 and 8, that is, 1<R2:R1<8. For a comparison of the light-emitting diode structure in which the second chamfer portion 141 and the first chamfer portion 151 have different radii of curvature, see FIG. 9, and this technical solution is to be described in detail in Example 2.

In an embodiment, a straight line distance between a center point of an arc side the first chamfer portion 151 and a center point of an arc side the second chamfer portion 141 is a maximum spacing D between the first chamfer portion 151 and the second chamfer portion 141, and a ratio of the maximum spacing D to the minimum distance L is greater than \sqrt{2}, that is D: L>\sqrt{2}. By further controlling the distance between the positions where the tip effect is most likely to occur at the corners of the first electrode 150 and the second mesa 140, it is ensured that even if the radii of curvature of the chamfer portions are not large enough to completely eliminate charge accumulation, leakage caused by ESD breakdown may be avoided by controlling the distance between the two charge accumulation points. With reference to FIG. 9, the technical solution of D:L>\sqrt{2} is to be described in detail in Example 2.

The light-emitting diode provided in this embodiment further includes a second electrode 160. The second electrode 160 is formed on one side of the light output surface of the semiconductor stack layer 120 and contacts the second semiconductor layer 123. A material of the electrode structure is selected from at least one of gold, silver, copper, aluminum, chromium, nickel, titanium, platinum, or at least one of alloys or laminates of the above materials.

### Example 2

With reference to FIG. 2 and FIG. 7 to FIG. 9, in this embodiment, a light-emitting diode is also provided, and the light-emitting diode at least includes a semiconductor stack layer 120 and a first electrode 150 formed on a back surface of the semiconductor stack layer 120.

Specifically, the semiconductor stack layer 120 has a light output surface and the back surface opposite to each other, and includes a first semiconductor layer 121, an active layer 122, and a second semiconductor layer 123 stacked in sequence in a direction from the light output surface to the back surface. On one side of the back surface of the semiconductor stack layer 120, the semiconductor stack layer 120 has a first mesa 130 exposing the first semiconductor layer 121 and a second mesa 140 adjacent to the first mesa 130. It can be understood that the first semiconductor layer 121 may be an N-type semiconductor layer and provides electrons to the active layer 122 under the action of a power source. The active layer 122 may be a quantum well (QW) structure or a multiple quantum well (MQW) structure. A composition and a thickness of a well layer in the active layer 122 determine a wavelength of the generated light. By changing the depth of the quantum wells, the number of pairs of quantum wells and quantum barriers, the thickness and/or other features in the active layer, the luminous efficiency may be improved. The second semiconductor layer 123 may be a P-type semiconductor layer and provides electron holes to the active layer 122 under the action of the power supply. Accordingly, a light output direction of the light output surface is away from a stack forming direction of the second mesa 140.

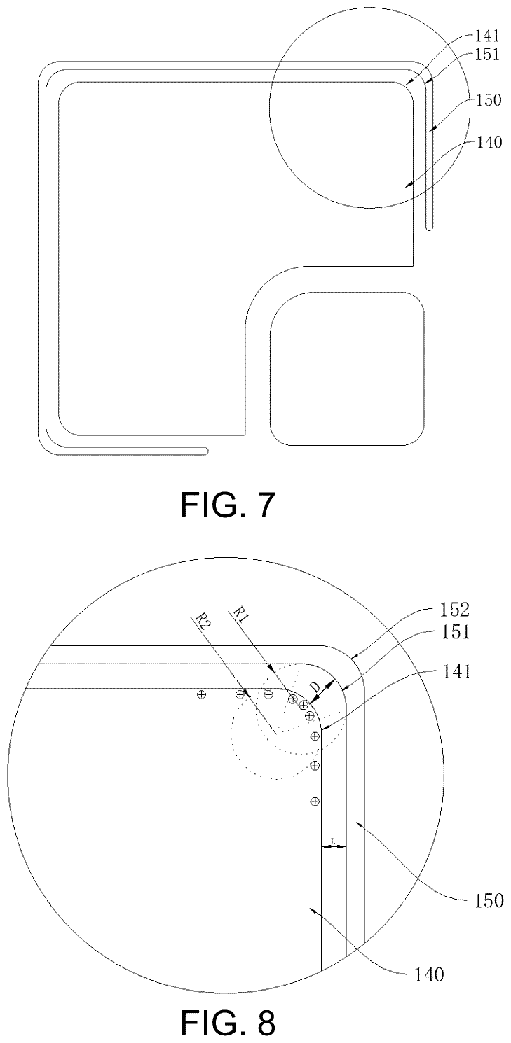

The first electrode 150 is formed on the back surface of the semiconductor stack layer 120, and the first electrode 150 surrounds at least a portion of the second mesa 140 in the xy plane. With reference to FIG. 1 or FIG. 7, approximately three quarters of an edge of the second mesa 140 is surrounded by the first electrode 150, and the first electrode 150 surrounding an edge region of the second mesa 140 extends toward the light output surface. That is, the first electrode 150 extends in a direction away from the second mesa 140 to form a good ohmic contact with the first semiconductor layer 121.

Herein, in a top view direction of the semiconductor stack layer 120, the first electrode 150 has a first chamfer portion 151, the second mesa 140 has a second chamfer portion 141, and the first chamfer portion 151 and the second chamfer portion 141 are arranged correspondingly. That is, the first electrode 150 surrounding the second chamfer portion 141 of each second mesa 140 has the first chamfer portion 151. In this embodiment, a ratio of a radius of curvature of the second chamfer portion 141 to a radius of curvature of the first chamfer portion 151 is defined to be greater than or equal to 1. In the above technical solution, a relative distance between the first electrode 150 and a tip structure corresponding to the second mesa 140 is defined by defining the ratio of the radius of curvature of the second chamfer 141 to the radius of curvature of the first chamfer 151, so as to reduce the charge accumulation caused by the tip effect. Specifically, it is set that the ratio of the radius of curvature of the second chamfer portion 141 to the radius of curvature of the first chamfer portion 151 is greater than or equal to 1, that is, R2:R1≥1. No matter how the specific parameters of rounded corners of the first electrode 150 and the second mesa 140 are set, by defining the ratio, the distance between the first electrode 150 and the second mesa 140 at the tips or rounded corners may always be no less than a minimum distance L when the two are in a parallel position relationship. Making the second mesa 140 further away from the first electrode 150 at the chamfer can further prevent chiplet leakage caused by ESD breakdown, so the ability of the light-emitting diode to withstand forward ESD is improved, and product reliability is further enhanced.

In an embodiment, with reference to FIG. 7 to FIG. 9, the first electrode 150 and the second mesa 140 have the minimum distance L, and the radius of curvature of the second chamfer portion 141 is greater than or equal to \sqrt{2}L. Under the premise that the distance between the first electrode 150 and the second mesa 140 at the tips or rounded corners is always greater than the minimum distance when the two are in a parallel position relationship, the radius of curvature of the second chamfer portion 141 is further defined to be greater than or equal to \sqrt{2}L, and the rounded corner design of the second mesa 140 is optimized so that the second mesa 140 does not produce a sharp corner structure. In this way, the carriers are distributed more uniformly instead of being concentrated at the corners of the first electrode 150 and the second mesa 140, and the leakage problems caused by excessive tip effects are thereby effectively avoided.

In an embodiment, with reference to FIG. 7 to FIG. 9 again, the minimum distance L between the first electrode 150 and the second mesa 140 is in a range of 2 μm to 10 μm. If the electrode is in direct contact with or is excessively close to a light output mesa, ESD breakdown or short circuit may occur, a LED device may thus be damaged, and the photoelectric performance is thereby lowered. An appropriate spacing between the electrode and the light output mesa may reduce the concentration of the electric field, which helps to improve the light output efficiency and brightness of the LED. The improved spacing may also be used to design heat dissipation and packaging structures to ensure that the LED device may effectively dissipate heat when working for a long time, and the service life of the LED is thus extended. However, if the spacing is excessively large, the effective light-emitting area may be lost, resulting in a decrease in brightness. Therefore, the minimum distance L between the first electrode 150 and the second mesa 140 is defined to a range of 2 μm to 10 μm to balance the performance of the above light emitting-diode. As an example, the minimum distance L may be 2 μm, 4 μm, 5.5 μm, 8 μm, or 10 μm. In this example, as in Embodiment 1, the minimum distance L is also set to 5.5 μm.

It can be understood that a straight line distance between a center point of an arc side the first chamfer portion 151 and a center point of an arc side the second chamfer portion 141 is a maximum spacing D between the first chamfer portion 151 and the second chamfer portion 141. With reference to FIG. 8, when the radius of curvature of the first chamfer portion 151 and the radius of curvature of the second chamfer portion 141 are the same, a ratio of the maximum spacing D to the minimum distance L is \sqrt{2}. By increasing sizes of the rounded corners of the light-emitting mesa and the first electrode 150 and limiting changes in the radii of curvature of the chamfer portions of the light-emitting mesa and the first electrode 150, the charges originally accumulated at the tip of the structure are gradually dispersed away from the tip, and the occurrence of tip effect is avoided. With reference to FIG. 9, by further controlling the distance between the positions where the tip effect is most likely to occur at the corners of the first electrode 150 and the second mesa 140, the ratio of the maximum spacing D to the minimum distance L is greater than \sqrt{2}, it is ensured that even if the radii of curvature of the chamfer portions are not large enough to completely eliminate charge accumulation, leakage caused by ESD breakdown may also be avoided by controlling a sufficient maximum spacing D between the two charge accumulation points. It can be understood that when the ratio of the maximum spacing D to the minimum distance L is greater than \sqrt{2}, a small amount of charges is still concentrated in a center of the first chamfer portion 151. However, the charges originally accumulated on both sides of the center of the first chamfer portion 151 may be effectively dispersed. On the whole, the purpose of relatively uniform charge distribution is also achieved, and this technical solution is particularly suitable for structural optimization of small-sized chips.

As an example, under the premise of R1=10 μm, when R2=10 μm, the maximum spacing D=\sqrt{2}L, and when R2=20 μm, 25 μm, or 30 μm, the maximum spacing D>\sqrt{2}L. It can be seen from the calculation results that under the premise that R1=10 μm remains unchanged, as R2 increases, the maximum spacing D gradually increases, the electric field distribution of the light-emitting diode becomes more uniform, and the carrier distribution becomes more dispersed. Further, at the rounded corners, the tip effect causing ESD breakdown and leakage may not easily occur.

In an embodiment, the radius of curvature of the second chamfer portion 141 is 10 μm to 60 μm. Further, the radius of curvature of the second chamfer portion 141 is in the range of 15 μm to 45 μm, so as to reduce the charge accumulation at the corner of the second mesa 140 as much as possible. In this way, a relatively large light output area is retained, brightness loss is reduced, and a performance balance is achieved. As an example, the radius of curvature of the second chamfer portion 141 may be 10 μm, 15 μm, 30 μm, 30 μm, 45 μm, 50 μm, or 60 μm.

In an embodiment, the radius of curvature of the first chamfer portion 151 is 5 μm to 60 μm. Further, the first chamfer portion 151 has a radius of curvature of 5 μm to 40 μm to match the round-corner structure of the second chamfer portion 141. As an example, the first chamfer portion 151 may have a radius of curvature of 5 μm, 10 μm, 20 μm, 30 μm, 40 μm, 50 μm, or 60 μm.

In an embodiment, the ratio of the radius of curvature of the second chamfer portion 141 to the radius of curvature of the first chamfer portion 151 is between 1 and 8, that is, 1<R2:R1<8. The larger the ratio value, the farther the second mesa 140 is from the first electrode 150 at the rounded corner of the light-emitting region. By enlarging the maximum distance between the second mesa 140 and the first electrode 150, chiplet leakage caused by ESD breakdown is further avoided. Further, the ratio of the radius of curvature of the second chamfer portion 141 to the radius of curvature of the first chamfer portion 151 is between 2 and 6, that is, 2<R2:R1<6. In this way, a balance may be achieved between the brightness loss caused by the reduction of the light-emitting area and the leakage defects caused by the enhanced tip effect.

In an embodiment, in the top view direction of the semiconductor stack layer 120, the first electrode 150 surrounding the second mesa 140 has a width, a chamfer portion close to the second mesa 140 is defined as the first chamfer portion 151, and a chamfer portion away from the second mesa 140 is defined as a third chamfer portion 152. Herein, the first chamfer portion 151 and the third chamfer portion 152 have a same curvature change rate, that is, a thickness of the first electrode 150 always remains unchanged. The inner and outer structures of the corners are all rounded structures with consistent curvature radius changes, which prevents the generation of stress concentration points or charge accumulation points caused by thinning of thickness or uneven thickness of the first electrode due to the rounded corners. In this way, the electrode structural strength is ensured while avoiding the tip effect.

### Example 3

With reference to FIG. 10, the disclosure further provides a light-emitting device including a circuit substrate 10 and a light-emitting element 20 fixed to the circuit substrate, and the light-emitting element 20 includes the light-emitting diode in the technical solution of Examples 1 to 2. The light-emitting device provided by the disclosure uses the light-emitting diode with good reliability provided in the above technical solution, so the light-emitting device also has good light output effect and improved service life.

The above-mentioned embodiments only illustrate the principles and effects of the disclosure, but are not intended to limit the disclosure. A person having ordinary skill in the art can modify or change the abovementioned embodiments without departing from the spirit and scope of the disclosure. Therefore, all equivalent modifications or changes made by a person having ordinary skill in the art without departing from the spirit and technical ideas disclosed in the disclosure shall still be covered by the claims of the disclosure.

What is claimed is:

1. A light-emitting diode, at least comprising:
a semiconductor stack layer having a light output surface and a back surface opposite to each other, and comprising a first semiconductor layer, an active layer, and a second semiconductor layer stacked in sequence in a direction from the light output surface to the back surface, wherein on one side of the back surface, the semiconductor stack layer has a first mesa exposing the first semiconductor layer and a second mesa adjacent to the first mesa; and
a first electrode formed on the back surface of the semiconductor stack layer and at least surrounding a portion of the second mesa, and the first electrode surrounding a portion of the second mesa extends toward the light output surface,
wherein in a top view direction of the semiconductor stack layer, the first electrode has a first chamfer portion, the second mesa has a second chamfer portion, and the first chamfer portion and the second chamfer portion are arranged correspondingly, and
the first electrode and the second mesa have a minimum distance L, and a radius of curvature of the second chamfer portion is greater than or equal to \sqrt{2}L.

2. The light-emitting diode according to claim 1, wherein a radius of curvature of the first chamfer portion is greater than or equal to \sqrt{2}L.

3. The light-emitting diode according to claim 1, wherein the minimum distance L between the first electrode and the second mesa is in a range of 2 μm to 10 μm.

4. The light-emitting diode according to claim 1, wherein the second mesa has a shortest side, and a radius of curvature of the first chamfer portion and the radius of curvature of the second chamfer portion are both less than half of a length of the shortest side.

5. The light-emitting diode according to claim 1, wherein the radius of curvature of the second chamfer portion is the same as or different from a radius of curvature of the first chamfer portion.

6. The light-emitting diode according to claim 5, wherein the radius of curvature of the second chamfer portion is 10 μm to 60 μm.

7. The light-emitting diode according to claim 5, wherein the radius of curvature of the first chamfer portion is 5 μm to 60 μm.

8. The light-emitting diode according to claim 5, wherein a ratio of the radius of curvature of the second chamfer portion to the radius of curvature of the first chamfer portion is greater than 1.

9. The light-emitting diode according to claim 8, wherein the ratio of the radius of curvature of the second chamfer portion to the radius of curvature of the first chamfer portion is between 1 and 8.

10. The light-emitting diode according to claim 8, wherein a straight line distance between a center point of the first chamfer portion and a center point of the second chamfer portion is a maximum spacing D between the first chamfer portion and the second chamfer portion, and a ratio of the maximum spacing D to the minimum distance L is greater than \sqrt{2}.

11. A light-emitting diode, at least comprising:
a semiconductor stack layer having a light output surface and a back surface opposite to each other, and comprising a first semiconductor layer, an active layer, and a second semiconductor layer stacked in sequence in a direction from the light output surface to the back surface, wherein on one side of the back surface, the semiconductor stack layer has a first mesa exposing the first semiconductor layer and a second mesa adjacent to the first mesa; and
a first electrode formed on the back surface of the semiconductor stack layer and at least surrounding a portion of the second mesa, and the first electrode surrounding a portion of the second mesa extends toward the light output surface,
wherein in a top view direction of the semiconductor stack layer, the first electrode has a first chamfer portion, the second mesa has a second chamfer portion, and the first chamfer portion and the second chamfer portion are arranged correspondingly, and
a ratio of a radius of curvature of the second chamfer portion to a radius of curvature of the first chamfer portion is greater than or equal to 1.

12. The light-emitting diode according to claim 11, wherein the first electrode and the second mesa have a minimum distance L, and a radius of curvature of the second chamfer portion is greater than or equal to \sqrt{2}L.

13. The light-emitting diode according to claim 11, wherein the radius of curvature of the second chamfer portion is 10 μm to 60 μm.

14. The light-emitting diode according to claim 11, wherein the radius of curvature of the first chamfer portion is 5 μm to 60 μm.

15. The light-emitting diode according to claim 11, wherein the ratio of the radius of curvature of the second chamfer portion to the radius of curvature of the first chamfer portion is between 1 and 8.

16. The light-emitting diode according to claim 1, wherein in the top view direction of the semiconductor stack layer, the first electrode surrounding the second mesa has a width, a chamfer portion close to the second mesa is defined as the first chamfer portion, and a chamfer portion away from the second mesa is defined as a third chamfer portion, wherein the first chamfer portion and the third chamfer portion have a same curvature change rate.

17. The light-emitting diode according to claim 11, wherein in the top view direction of the semiconductor stack layer, the first electrode surrounding the second mesa has a width, a chamfer portion close to the second mesa is defined as the first chamfer portion, and a chamfer portion away from the second mesa is defined as a third chamfer portion, wherein the first chamfer portion and the third chamfer portion have a same curvature change rate.

18. A light-emitting device comprising a circuit substrate and a light-emitting element fixed to the circuit substrate, wherein the light-emitting element comprises at least one light-emitting diode according to claim 1.

19. A light-emitting device comprising a circuit substrate and a light-emitting element fixed to the circuit substrate, wherein the light-emitting clement comprises at least one light-emitting diode according to claim 11.
